(19) United States
(12) Patent Application Publication
(10) Pub. No.: US 2007/0035318 A1
(43) Pub. Date: Feb. 15, 2007

(54) Donut-type parallel probe card and method of testing semiconductor wafer using same

(76) Inventors: Sang-kyu Yoo, Suwon-si (KR); Sung-mo Kang, Suwon-si (KR); Chang-hyun Cho, Suwon-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/500,466

(22) Filed: Aug. 8, 2006

(30) Foreign Application Priority Data
Aug. 9, 2005 (KR) 10-2005-0072995

(51) Int. Cl. G01R 31/02

(52) U.S. Cl. 324/754

(57) ABSTRACT

A donut-type parallel probe card comprises a main substrate and a plurality of probing blocks installed on a surface of the main substrate, wherein each probe block comprises a plurality of probes. The probing blocks are arranged to fill a first region having an oval shape and surrounding a second region, and no probing blocks are arranged within the second region.

### BACKGROUND OF THE INVENTION

1. Field of the Invention

Embodiments of the invention relate generally to techniques and equipment for electrically testing a semiconductor wafer. More particularly, embodiments of the invention relate to a parallel probe card used when an electrical die sort (EDS) test and a wafer burn-in test are conducted on a semiconductor wafer.

A claim of priority is made to Korean Patent Application No. 10-2005-0072995 filed on Aug. 9, 2005, the disclosure of which is hereby incorporated by reference in its entirety.

2. Description of Related Art

Electrical die sort (EDS) testing is commonly used to identify bad die prior to integrated circuit (IC) packaging. In an EDS test, the electrical performance and circuit functioning of each die on a semiconductor wafer is tested. If a die passes all of the tests, the die can be packaged to form a semiconductor device. However, if the die fails one or more of the tests, the die is either repaired using some form of redundant circuitry within the die, or the die is used with limited functionality, or the die is discarded. In many cases, die must be discarded, thus lowering the yield and increasing the average cost of semiconductor manufacturing. However, by performing the EDS testing prior to packaging, at least the cost of packaging bad die is saved.

EDS testing is typically conducted using a tester and a probe station. The tester generally comprises a probe card including a set of microscopic contacts or probes that are held in place during the EDS testing, and automatic test equipment (ATE) used to generate electrical signals and transmit the electrical signals to the probes of the probe card. The probe station comprises automatic transportation and alignment equipment that moves a semiconductor wafer into alignment with the probes of the probe card for testing. Once connected with the probes of the probe card, the semiconductor wafer using the electrical signals generated by the ATE.

The ATE used in the EDS testing is typically very expensive. As a result, various techniques have been developed to maximize the efficiency with which the ATE is used. One way to increase the efficiency with which the ATE is used is to reduce the time required to perform EDS testing on each wafer. Another way to increase the efficiency with which the ATE is used is to conduct testing of several wafers in parallel. For example, parallel EDS testing can be performed on 64 to 256 chips.

FIG. 1 is a sectional view illustrating a conventional probe card 500 having a plurality of vertical probes 100 and used to test a plurality of wafers 600. Most conventional probes are horizontal or diagonal. However, as the integration density of semiconductor chips has increased, probes such as vertical probes 100 which have narrower widths have become more widely used.

Wafers 600 are loaded onto and aligned on a testing table 700 in a probe station. Tens through hundreds of chips 610 are formed on each of wafers 600. Probe card 500 is an interface unit which precisely connects pads 611 on each of chips 610 to vertical probes 100.

Probe card 500 comprises a main substrate 300 having conductive patterns 310, guide plates 210 and 220, a pair of posts 250, and vertical probes 100 installed in through-holes 320 formed in main substrate 300 and guide plates 210 and 220. The EDS test is conducted by contacting tips 110 of probes 100 with corresponding pads 611 on each of chips 610.

A conventional method of electrically testing wafers using such vertical probes is disclosed, for example, in U.S. Pat. No. 6,853,208 entitled “Vertical Probe Card.”

FIG. 2 is a plan view of probe card 500 with some variations from FIG. 1. In particular, in FIG. 2, probe card 500 includes a plurality of probing blocks 400 connected to main substrate 300. Main substrate 300 includes a conductive patterns, and each of probing blocks 400 includes a bundle of vertical probes 100 with contacting tips 110 used to electrically test each chip. To conduct EDS testing on, for example, 256 chips in parallel, 256 probing blocks 400 are required. As illustrated in FIG. 2, probing blocks 400 form a 16×16 square.

FIGS. 3 through 5 are plan views illustrating a method of testing a 300 mm wafer 600 using probe card 500 of FIG. 2. Wafers 600 in FIGS. 3 through 5 include chips 610 that are tested using EDS testing, and also portions 620 to which probe card 500 is connected, but which are not electrically functional. In other words, chips 610 are formed in a circular pattern denoted by a shaded squares and surrounded by a broken circle, but EDS testing takes place on a square area of wafer 600 indicated by a bold line due to the square formation of probing blocks 400.

FIG. 3 shows a left portion of wafer 600 that is tested in a first shot using probe card 500, FIG. 4 shows a right portion of wafer 600 that is tested in a second shot using probe card 500, FIG. 5 shows a center portion of wafer 600 that is tested in a third shot using probe card 500.

In the first and second shots, portions 620 are tested by probing blocks 400 even though there are no circuit patterns formed on portions 620. In addition, the third shot tests many of chips 610 that were already tested in the first and second shots. The tests of portions 620, and the redundant tests of chips 610 are unnecessary, and therefore decrease test efficiency and increase the time required to test wafer 600.

### SUMMARY OF THE INVENTION

According to one embodiment of the present invention, a donut-type parallel probe card comprises a main substrate, and a plurality of probing blocks installed on a surface of the main substrate. Each probe block comprises a plurality of probes, and the probing blocks are arranged to fill a first region having an oval shape and surrounding a second region. No probing blocks are arranged within the second region.

According to another embodiment of the present invention, a donut-type parallel probe card adapted to perform a wafer burn-in test comprises a main substrate, and a plurality of probing blocks installed on a surface of the main substrate. Each probe block comprises a plurality of probes, and the probing blocks are arranged to fill a first region having an oval shape and surrounding a second region, and no probing blocks are arranged within the second region.

According to still another embodiment of the invention, a method of testing a wafer using a donut-type parallel probe card is provided. In the method, the donut-type parallel probe card comprises a main substrate and a plurality of probing blocks installed on a surface of the main substrate. Each probe block comprises a plurality of probes, and the probing blocks are arranged to fill a first region having an oval shape and surrounding a second region, but no probing blocks are arranged within the second region. The method comprises conducting a first electrical test in which chips in a first portion of the wafer corresponding to the first region are electrically tested using the donut-type parallel probe card while chips in a second portion of the wafer corresponding to the second region are not tested. The method further comprises conducting a second electrical test in which chips in a second portion of the wafer and the chips corresponding to the second region which were not tested in the first electrical test are electrically tested.

### BRIEF DESCRIPTION OF THE DRAWINGS

The invention is described below in relation to several embodiments illustrated in the accompanying drawings. Throughout the drawings like reference numbers indicate like exemplary elements, components, or steps. In the drawings:

FIG. 1 is a sectional view illustrating a conventional probe card which has a plurality of vertical probes and is used to test a plurality of wafers;

FIG. 2 is a plan view of a variation of the probe card shown in FIG. 1

FIGS. 3 through 5 are plan views illustrating a method of testing a wafer using the probe card shown in FIG. 2;

FIG. 6 is a plan view of a parallel probe card having a plurality of probing blocks arranged in a donut shape according to an embodiment of the present invention;

FIGS. 7 and 8 are plan views illustrating a method of testing a wafer using the parallel probe card of FIG. 6 according to selected embodiments of the invention;

FIGS. 9A though 9C are plan views of probing blocks each comprising a plurality of probes arranged according to embodiments of the invention; and,

FIG. 10 is a flowchart illustrating a method of fabricating a semiconductor package using the parallel probe card of FIG. 6.

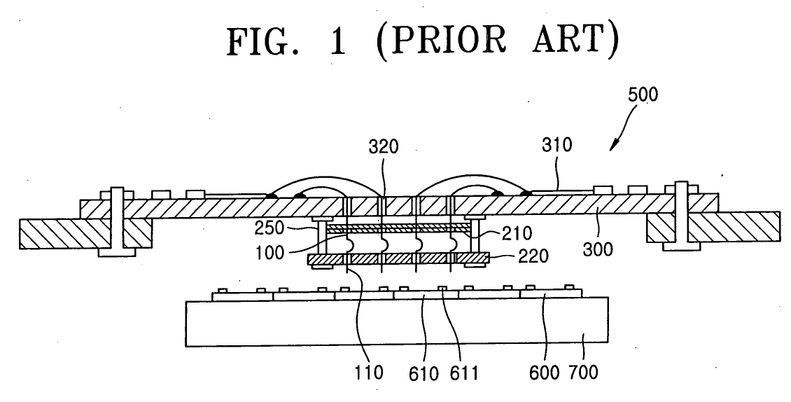

### DESCRIPTION OF EXEMPLARY EMBODIMENTS

Exemplary embodiments of the invention are described below with reference to the corresponding drawings. These embodiments are presented as teaching examples. The actual scope of the invention is defined by the claims that follow.

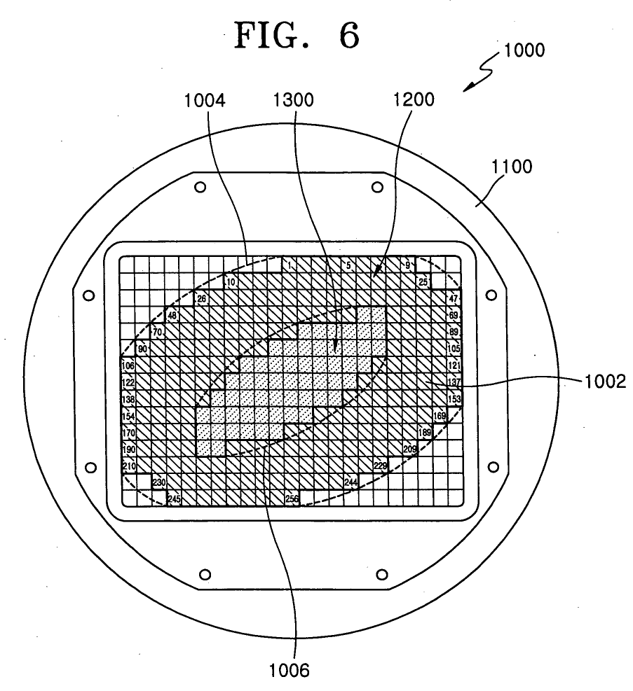

FIG. 6 is a plan view of a parallel probe card 1000 having a plurality of probing blocks 1002 arranged in a donut shape according to an embodiment of the present invention. The parallel probe card will be referred to hereafter as a donut-type parallel probe card 1000.

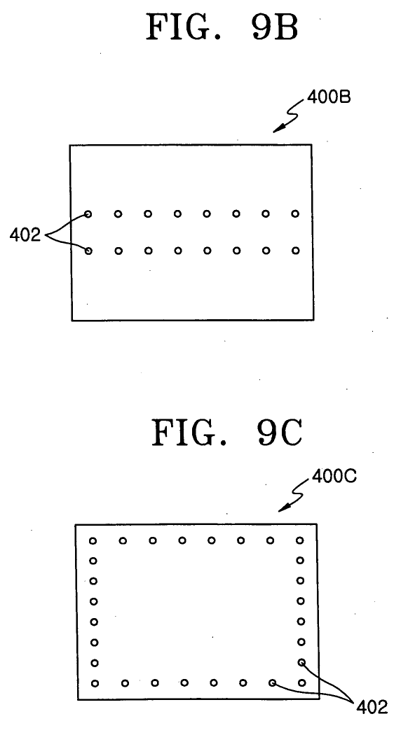

Referring to FIG. 6, donut-type parallel probe card 1000 includes a main substrate 1100 having conductive patterns and probing blocks 1002 installed on a surface of main substrate 1100. Probing blocks 1002 include probes corresponding to pads on respective individual chips. Probing blocks 1002 are described in further detail below with reference to FIG. 9.

Unlike conventional probing blocks, probing blocks 1002 of donut-type parallel probe card 1000 have a donut shape rather than a square shape. In other words, probing blocks 1002 are installed in a first region 1200 within a first oval 1004, but not in a second region 1300 within a second oval 1006 inside first oval 1004. In FIG. 6, first and second regions 1200 and 1300 are delimited by bold lines arranged in rectilinear shapes, while first and second ovals 1004 and 1006 are delimited by broken curved lines.

Since probing blocks 1002 are arranged in the structure shown in FIG. 6, the number of probing blocks 1002 that are not connected to chips on a wafer when the chips are electrically tested using donut-type parallel probe card 1000 can be minimized. Furthermore, instances where chips are redundantly tested in successive tests can also be minimized.

In FIG. 6, 256 probing blocks 1002 are illustrated. However, the number of probing blocks 1002 can be reduced, for example, to 128, 64, or 32. In addition, the number of chips that can be tested in parallel can also be increased, for example, by changing the number of probing blocks 1002 to 512 or 1024.

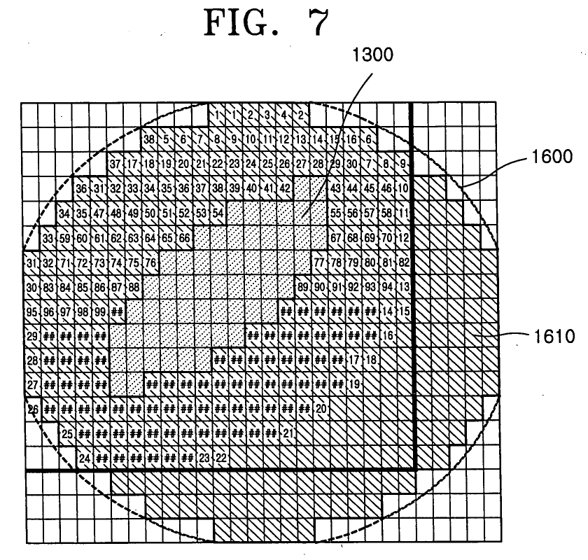

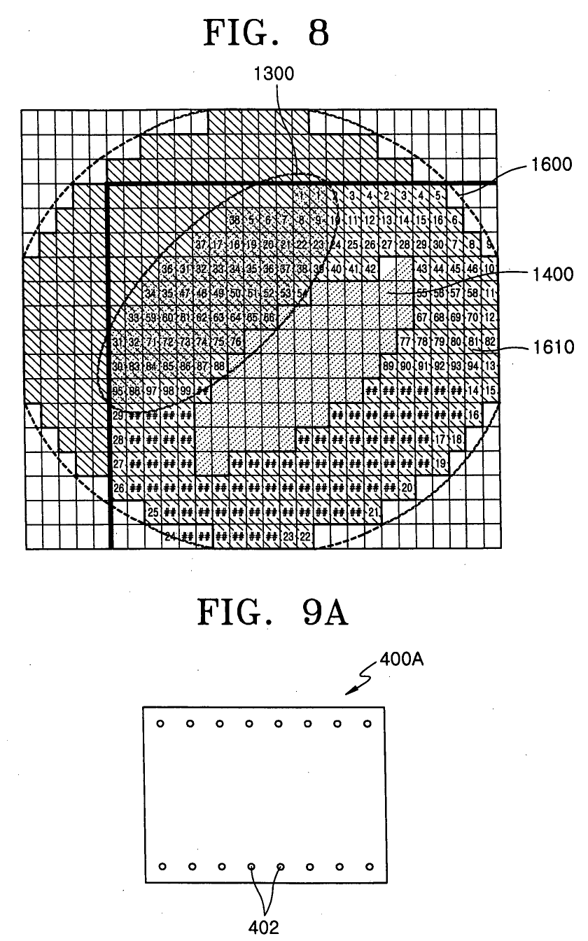

FIGS. 7 and 8 are plan views illustrating methods for testing a wafer 1600 using donut-type parallel probe card 1000 shown in FIG. 6.

In a first shot illustrated in FIG. 7, donut-type parallel probe card 1000 is placed over an upper left area of wafer 1600 delimited by a bold line, and chips 1610 labeled with one or two digit numbers or the “##” symbol are tested. In a second shot illustrated in FIG. 8, donut-type parallel probe card 1000 is placed over a lower right area of wafer 1600 delimited by a bold line, and chips 1610 labeled with one or two digit numbers or the “##” symbol are tested.

In FIG. 7, second region 1300 of FIG. 6 is marked to show where chips 1610 corresponding to center portion of donut-type parallel probe card 1000 are not tested in the first shot using probing blocks 1002. In FIG. 8, a region 1400 is marked to show where chips 1610 corresponding to the center portion of donut-type parallel probe card 100 are not tested in the second shot using probing blocks 1002.

Chips 1610 in second region 1300 are tested only once—in the second shot illustrated in FIG. 8. Chips 1610 in region 1400 are also tested only once—in the first shot illustrated in FIG. 7. Because these chips 1610 are only tested once, a large number of redundant chip tests can be avoided. In addition, as illustrated by FIGS. 7 and 8, all of wafer 1600 can be tested in two rather than three shots, thereby reducing the time required for EDS testing by approximately 33% relative to conventional approaches.

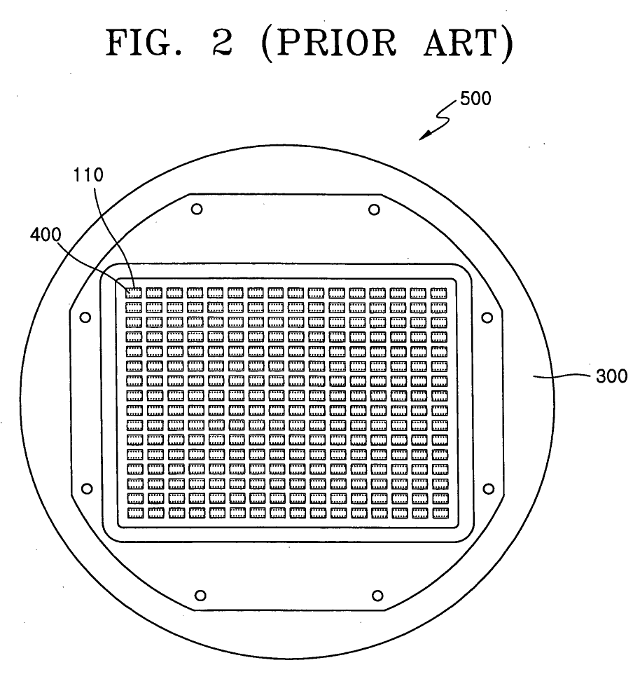

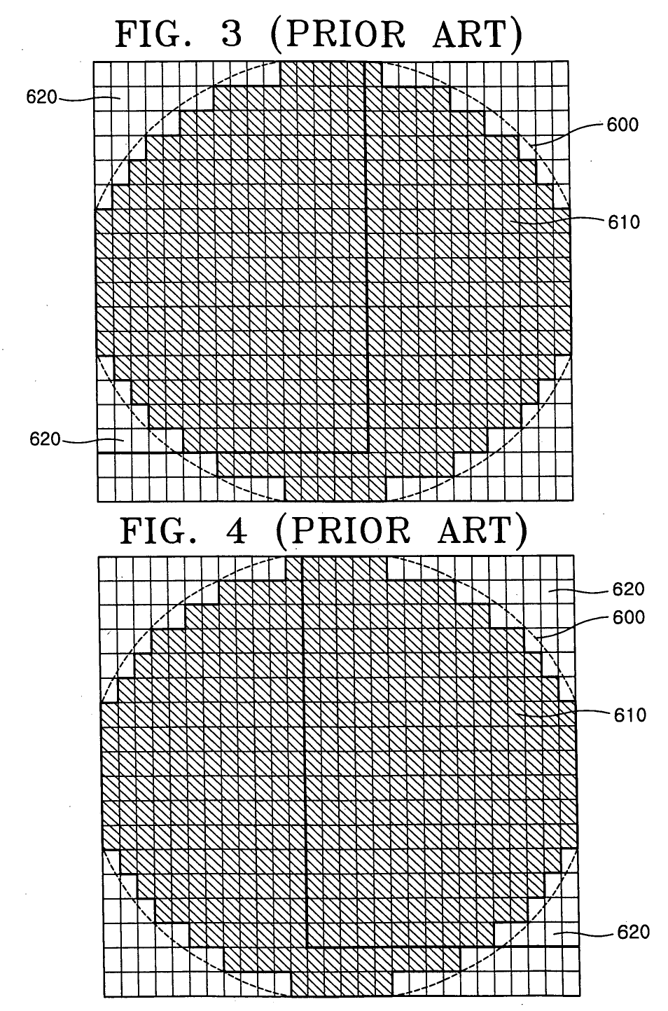

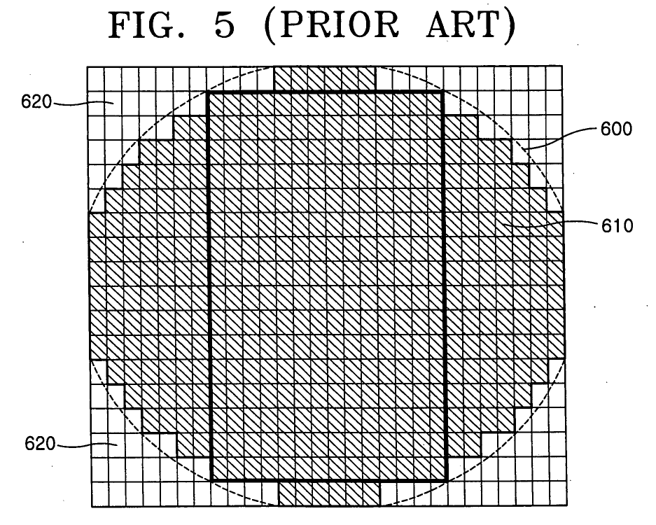

As an example of the time required to perform EDS testing, a single shot of an EDS test for a 4-Gigabit NAND flash memory device typically requires 1000 seconds or 17 minutes. Accordingly, where three shots are required per wafer, as when using a conventional square probe card such as that illustrated in FIG. 2, it takes 1 hour and 42 minutes (17×6=102 minutes) to conduct EDS testing on two wafers of a 4-Gigabit NAND flash memory device. However, where donut-type parallel probe card 1000 of FIG. 6 is used, the test time is reduced to 1 hour and 8 minutes (17×4=68 minutes) since only four shots of EDS testing are required. By thus reducing the time required for EDS testing, the cost of manufacturing semiconductor devices is reduced accordingly.

Donut-type parallel probe card 1000 of FIG. 6 can be applied to wafers of all types, although applying probe card to a 300 mm wafer has been described as an example. In addition, a test of a NAND flash memory device using donut-type parallel probe card 1000 was also described as an example. Donut-type parallel probe card 1000 can be used to conduct EDS testing on all types of semiconductor devices that can be tested in parallel.

FIGS. 9A though 9C are plan views of probing blocks 400A, 400B, and 400C in each of which a plurality of probes 402 are arranged according to various embodiments of the present invention.

Referring to FIGS. 9A through 9C, probes 402 are installed in each of probing blocks 400A, 400B, and 400C. In FIG. 9A, probes 402 are arranged in a top and bottom pattern, in FIG. 9B, probes 402 are arranged in a center pattern, and in FIG. 9C, probes 402 are arranged in an edge pattern, In each of FIGS. 9A through 9C, the arrangement of probes 402 corresponds to the arrangement of pads on individual chips of a wafer to be tested.

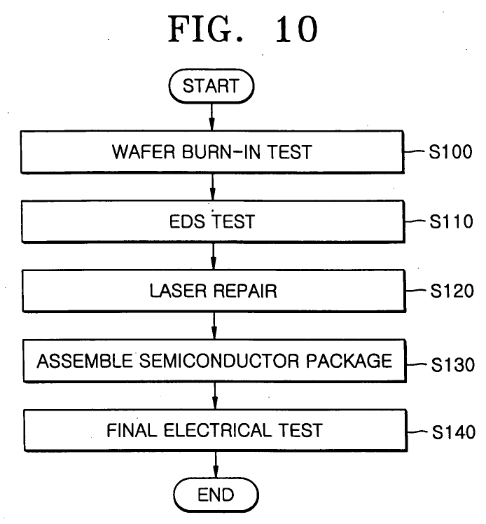

FIG. 10 is a flowchart illustrating a method of fabricating a semiconductor package using donut-type parallel probe card 1000 of FIG. 6 according to an embodiment of the present invention. In the description that follows, exemplary method steps are denoted by parentheses (XXX).

Referring to FIG. 10, the method comprises a wafer burn-in test (S100), an EDS test (S110), a laser repair (S120), assembly (S130), and a final electrical test (S140), which are sequentially performed when manufacturing a memory device. The wafer burin-in test (S100) is conducted on a semiconductor chip in a wafer state to remove initial defects from the semiconductor chip. The wafer burn-in test (S100) is conducted in parallel like the EDS test (S110) described above. Accordingly, the donut-type parallel probe card of FIG. 6 may also be used when performing the wafer burn-in test (S100).

As described above, according to selected embodiments of the invention, the pattern in which probing blocks are arranged in a probe card can be changed so that only two electrical tests or shots are required to test a wafer. Hence, the efficiency of a wafer burn-in test and an EDS test can be enhanced.

The foregoing preferred embodiments are teaching examples. Those of ordinary skill in the art will understand that various changes in form and details may be made to the exemplary embodiments without departing from the scope of the present invention as defined by the following claims.

What is claimed:

1. A donut-type parallel probe card comprising:
a main substrate; and,
a plurality of probing blocks installed on a surface of the main substrate, each probe block comprising a plurality of probes;
wherein the probing blocks are arranged to fill a first region having an oval shape and surrounding a second region, wherein no probing blocks are arranged within the second region.

2. The probe card of claim 1, wherein the probe card is adapted to perform an electrical die sort test on a memory chip.

3. The probe card of claim 1, wherein the probing blocks are adapted to test a 300 mm size wafer.

4. The probe card of claim 1, wherein the second region has an oval shape.

5. The probe card of claim 1, wherein a number of the probing blocks is 64, 128, or 256.

6. The probe card of claim 1, wherein an overall size of the probing blocks installed on the main substrate is large enough to test all chips on a wafer in two tests.

7. The probe card of claim 1, wherein the probes are installed vertically in the probing blocks.

8. The probe card of claim 7, the plurality of probes are arranged on one or more of the probing blocks in a center pattern.

9. The probe card of claim 7, the plurality of probes are arranged on one or more of the probing blocks in an edge pattern.

10. The probe card of claim 7, the plurality of probes are arranged on one or more of the probing blocks in a top and bottom pattern.

11. A donut-type parallel probe card adapted to perform a wafer burn-in test, the probe card comprising:
a main substrate; and,
a plurality of probing blocks installed on a surface of the main substrate, each probe block comprising a plurality of probes;
wherein the probing blocks are arranged to fill a first region having an oval shape and surrounding a second region, wherein no probing blocks are arranged within the second region.

12. The probe card of claim 11, wherein an overall size of the probing blocks installed on the main substrate is large enough to test all chips on a wafer in two tests.

13. The probe card of claim 11, wherein the probes are installed vertically in the probing blocks.

14. The probe card of claim 11, wherein the second region has an oval shape.

15. A method of testing a wafer using a donut-type parallel probe card, wherein the donut-type parallel probe card comprises a main substrate and a plurality of probing blocks installed on a surface of the main substrate, wherein each probe block comprising a plurality of probes, and wherein the probing blocks are arranged to fill a first region having an oval shape and surrounding a second region, wherein no probing blocks are arranged within the second region,
the method comprising:
conducting a first electrical test in which chips in a first portion of the wafer corresponding to the first region are electrically tested using the donut-type parallel probe card while chips in a second portion of the wafer corresponding to the second region are not tested;
conducting a second electrical test in which chips in a second portion of the wafer and the chips corresponding to the second region which were not tested in the first electrical test are electrically tested.

16. The method of claim 15, wherein the first and second electrical tests are electrical die sort tests.

17. The method of claim 15, wherein the first and second electrical tests are wafer burn-in tests.

18. The method of claim 15, wherein a plurality of probes corresponding to the chips on the wafer are installed vertically in the probing blocks.

19. The method of claim 18, wherein the probes are installed in each probing block in a center pattern, an edge pattern, or a top and bottom pattern.

20. The method of claim 15, wherein the second region has an oval shape.
